(19) United States
(12) Patent Application Publication
(10) Pub. No.: US 2010/0084167 A1
(43) Pub. Date: Apr. 8, 2010

(54) SUBSTRATE APPLICABLE IN CHIP LED PACKAGE

(75) Inventors: Changbo SHIM, Goesan-gun (KR); Toyonari ITO, Tsukuba-shi (JP); Satoshi OKAMOTO, Tsukuba-shi (JP)

Correspondence Address: PANITCH SCHWARZE BELISARIO & NADEL LLP, ONE COMMERCE SQUARE, 2005 MARKET STREET, SUITE 2200, PHILADELPHIA, PA, 19103, US

(73) Assignee: SUMITOMO CHEMICAL COMPANY, LIMITED, Chuo-ku (JP)

(21) Appl. No.: 12/573,344

(22) Filed: Oct. 5, 2009

(30) Foreign Application Priority Data
Oct. 8, 2008 (JP) 2008-261393

(51) Int. Cl. H05K 7/20; B05D 5/12

(52) U.S. Cl. 174/252; 427/99.4

(57) ABSTRACT

The present invention provides a substrate applicable in a chip LED package, the substrate having a conductive layer, an insulation layer and a heat-dissipation plate in this order, wherein the insulation layer comprises a liquid crystal polyester soluble in a solvent and a sheet comprising inorganic fibers and/or organic fibers. The substrate has a small linear expansion coefficient of the insulation layer in the surface direction and is extremely useful for production of a chip LED package while having a practical heat resistance.

### BACKGROUND OF THE INVENTION

1. Field of the Invention

The present invention relates to a substrate applicable in a chip LED package and a chip LED package using the substrate.

2. Description of the Background Art

In recent years, additional values such as outer appearance, operability, and visibility are demanded in a display that is mounted on an electronic apparatus such as a portable phone or a camera-integrated type VTR. For this reason, as a light source of a light-emitting apparatus thereof, a LED (light emitting diode) producing a high visual effect and having a small scale with a small electric power consumption is regarded as being important. Up until now, in a light-emitting apparatus using a LED, a bullet-type LED has been mainly used. However, in order to meet further scale reduction or thickness reduction of electronic apparatus, use of a chip LED package having a LED mounted on a substrate surface is increasing.

As a substrate used in such a chip LED package, a laminate plate using a prepreg (a sheet-form glass fiber base material impregnated with a thermosetting resin) as an insulation layer and obtained by pressing and laminating a copper foil onto the prepreg is used. For example, Japanese Patent Application Laid-Open (JP-A) No. 2006-316173 proposes a substrate using a prepreg formed with an alicyclic epoxy resin and a sheet-form glass fiber base material as an insulation layer.

However, when a chip LED package is produced using a substrate disclosed in JP-A No. 2006-316173, the reliability of the chip LED package has not been necessarily satisfactory.

### SUMMARY OF THE INVENTION

The present inventors and others have made eager studies on the cause thereof and, as a result thereof, have made it clear that, in a substrate using such an epoxy resin for an insulation layer, the linear expansion coefficient of the insulation layer along a direction parallel to the substrate surface (hereafter referred to as a “linear expansion coefficient along the surface direction”) is comparatively large, thereby possibly giving adverse effects on the LED mounting part by the heat generation accompanying the operation of the chip LED package. Further, in even worse cases, there has been a problem in that the LED itself is exfoliated from the substrate. Also, in producing the chip LED package, a LED is generally mounted onto the substrate with use of a solder. Thus, heat resistance (solder resistance) is also strongly desired in the substrate.

Therefore, one of objects of the present invention is to provide a substrate having a smaller linear expansion coefficient of the insulation layer in the surface direction and being extremely useful in a chip LED package while having a practical heat resistance.

The present invention provides a substrate applicable in a chip LED package, the substrate having a conductive layer, an insulation layer and a heat-dissipation plate in this order, wherein the insulation layer is made of a liquid crystal polyester soluble in a solvent and a sheet comprising inorganic fibers and/or organic fibers.

The present invention also provides a chip LED package comprising the above-described substrate and a light emitting diode (LED).

The substrate of the present invention has characteristics of having a smaller linear expansion coefficient of the insulation layer in the surface direction (compared to the known insulation layer) while having a practically sufficient heat resistance. Therefore, the substrate is extremely useful for producing a chip LED package, which results in providing a chip LED package excellent in reliability. Further, a light-emitting apparatus provided with a chip LED package using the substrate of the present invention is industrially extremely useful because of having an extremely high reliability.

### BRIEF DESCRIPTION OF THE DRAWINGS

FIGS. 1(a) and 1(b) are cross-sectional model views showing steps for producing a copper-clad laminate plate in the present invention;

FIGS. 2(c) to 2(e) are cross-sectional model views showing steps for producing the substrate of the present invention; and

FIG. 3 is a cross-sectional model view showing a construction of the chip LED package of the present invention.

### DESCRIPTION OF THE PREFERRED EMBODIMENTS

A chip LED package is typically produced in such a way that a light-emitting diode (LED) may be mounted on a substrate. A substrate applicable in the chip LED package in the present invention has a conductive layer, an insulation layer and a heat-dissipation plate. For example, the substrate may be formed by laminating a conductive layer, an insulation layer and a heat-dissipation plate in this order. The insulation layer may be prepared using a liquid crystal polyester soluble in a solvent and a sheet made of inorganic fibers and/or organic fibers.

Hereafter, preferable embodiments of the present invention and methods for producing the embodiments are described. While reference will be made to the drawings in accordance with the needs, identical constituent elements will be denoted with identical symbols, and a duplicated description thereof will be omitted. Also, the dimension and the like of the constituent elements in the drawings are arbitrary for the sake of simplicity in viewing.

### <Liquid Crystal Polyester>

The liquid crystal polyester used in the present invention refers to a polyester provided with characteristics of exhibiting an optical anisotropic property at the time of melting, and forming an anisotropic melt at a temperature of 450° C. or lower. The liquid crystal polyester used in the present invention is preferably a liquid crystal polyester containing 30.0 to 45% by mole of a structural unit represented by the following formula (1), 27.5 to 35% by mole of a structural unit represented by the following formula (2), and 27.5 to 35% by mole of a structural unit represented by the following formula (3), all amounts of being relative to the total amount of all the structural units,

—O—Ar¹—CO— (1)

—CO—Ar²—CO— (2)

—X—Ar³—Y— (3).

In the formulas, Ar¹ represents a phenylene group or a naphthylene group; Ar² represents a phenylene group, a naphthylene group, or a group represented by the following formula (4); and Ar³ represents a phenylene group or a group represented by the following formula (4); X and Y each independently represent O or NH; and the hydrogen atoms attached to the aromatic rings Ar¹, Ar², and Ar³ may each independently be substituted with a halogen atom, an alkyl group, or an aryl group,

—Ar¹¹—Z—Ar¹²— (4).

In the formula (4), Ar¹¹ and Ar¹² each independently represent a phenylene group or a naphthylene group; and Z represents O, CO, or SO₂.

The structural unit (1) is a structural unit derived from aromatic hydroxycarboxylic acid, and examples of the aromatic hydroxycarboxylic acid include parahydroxybenzoic acid, metahydroxybenzoic acid, 2-hydroxy-6-naphthoic acid, 2-hydroxy-3-naphthoic acid, 1-hydroxy-4-naphthoic acid, and the like.

The structural unit (2) is a structural unit derived from aromatic dicarboxylic acid, and examples of the aromatic dicarboxylic acid include terephthalic acid, isophthalic acid, 2,6-naphthalenedicarboxylic acid, 1,5-naphthalenedicarboxylic acid, diphenylether-4,4′-dicarboxylic acid, diphenylsulfone-4,4′-dicarboxylic acid, diphenylketone-4,4′-dicarboxylic acid, and the like.

The structural unit (3) is a structural unit derived from aromatic diol, aromatic amine having a phenolic hydroxyl group, or aromatic diamine. Examples of the aromatic diol include hydroquinone, resorcin, bis(4-hydroxyphenyl)ether, bis(4-hydroxyphenyl)ketone, bis(4-hydroxyphenyl)sulfone, and the like.

Examples of the aromatic amine having a phenolic hydroxyl group include p-aminophenol, 3-aminophenol, and the like. Examples of the aromatic diamine include 1,4-phenylenediamine, 1,3-phenylenediamine, and the like.

The liquid crystal polyester used in the present invention is soluble in a solvent. Such a property of being soluble in a solvent means that it is dissolved in the solvent at a concentration of 1 wt % or more at a temperature of 50° C. The solvent in this case is any one kind of the suitable solvents used for preparation of a later-mentioned solution composition, and the detailed description thereof will be given later.

Such a liquid crystal polyester soluble in a solvent is preferably a liquid crystal polyester containing a structural unit derived from aromatic amine and/or aromatic diamine having a phenolic hydroxyl group as the structural unit (3). Namely, the structural unit (3) preferably contains a structural unit in which either one or both of X and Y is NH. More preferably, substantially all the structural units (3) are a structural unit represented by the following formula (3′) (hereafter, referred to as structural unit (3′)):

—X—Ar³—NH— (3′).

In the formula (3′), Ar³ and X have the same meaning as described above.

A liquid crystal polyester having a structural unit (3′) as the structural unit (3) has a more excellent solubility to a solvent, thereby also providing an advantage of further facilitating the production of an insulation layer using the later-mentioned solution composition.

The structural unit (1) is preferably contained in the range of 30 to 45% by mole, more preferably in the range of 35 to 40% by mole, relative to the total amount of all the structural units. A liquid crystal polyester containing the structural unit (1) in such a molar fraction ratio tends to have a more excellent solubility to a solvent while sufficiently maintaining the liquid crystallinity. Further, also in consideration of the obtainability of aromatic hydroxycarboxylic acid deriving the structural unit (1), the aromatic hydroxycarboxylic acid is preferably parahydroxybenzoic acid and/or 2-hydroxy-6-naphthoic acid.

The structural unit (2) is preferably contained in the range of 27.5 to 35% by mole, more preferably in the range of 30 to 32.5% by mole, relative to the total amount of all the structural units. A liquid crystal polyester containing the structural unit (2) in such a molar fraction ratio tends to have a more excellent solubility to a solvent while sufficiently maintaining the liquid crystallinity. Further, also in consideration of the to obtainability of aromatic dicarboxylic acid deriving the structural unit (2), the aromatic dicarboxylic acid is preferably at least one kind selected from the group consisting of terephthalic acid, isophthalic acid, and 2,6-naphthalenedicarboxylic acid.

The structural unit (3) is preferably contained in the range of 30 to 32.5% by mole, relative to the total amount of all the structural units. By setting the structural unit (3) in the range enables the solvent-solubility of the liquid crystal polyester to be further improved.

Also, in order for the obtained liquid crystal polyester to exhibit a high liquid crystallinity, the molar ratio of the structural unit (2) and the structural unit (3) is preferably within the range of 0.9/1 to 1/0.9 in terms of [structural unit (2)]/[structural unit (3)].

Next, a method of producing the liquid crystal polyester will be briefly described.

The liquid crystal polyester can be produced by various known methods. In producing a liquid crystal polyester made of the structural unit (1), the structural unit (2), and the structural unit (3), which is a suitable liquid crystal polyester, a method of converting the monomers deriving these structural units into ester-forming/amide-forming derivatives, and thereafter polymerizing these to produce the liquid crystal polyester is preferable because the operation is convenient.

The above described ester-forming/amide-forming derivatives will be described by way of examples. As the ester-forming/amide-forming derivatives of a monomer having a carboxyl group such as aromatic hydroxycarboxylic acid or aromatic dicarboxylic acid, examples thereof include those in which the carboxyl group becomes a group having a high reaction activity such as haloformyl group or acyloxycarbonyl group to form acid chloride or acid anhydride so as to promote a reaction of generating polyester or polyamide, those in which the carboxyl group forms an ester with alcohols or ethylene glycol so as to generate polyester or polyamide by ester exchange or amide exchange reaction, and the like.

Examples of the ester-forming/amide-forming derivatives of a monomer having a phenolic hydroxyl group such as aromatic hydroxycarboxylic acid or aromatic diol include those in which the phenolic hydroxyl group forms an ester with carboxylic acids so as to generate polyester or polyamide by ester exchange reaction, and the like.

Also, examples of the amide-forming derivative of a monomer having an amino group such as aromatic diamine include those in which the amino group forms an amide with carboxylic acids so as to form polyamide by amide exchange reaction.

Among these, in order to produce liquid crystal polyester more conveniently, a method of acylating aromatic hydroxycarboxylic acid and a monomer having a phenolic hydroxyl group and/or amino group such as aromatic diol or aromatic amine or aromatic diamine having a phenolic hydroxyl group with an aliphatic acid anhydride to form an ester-forming/amide-forming derivative (acylated product) and thereafter polymerizing the resultant so that the acyl group of the acylated product and the carboxyl group of the monomer having a carboxyl group will generate ester exchange/amide exchange, so as to produce a liquid crystal polyester is particularly preferable.

Such a method of producing a liquid crystal polyester is disclosed, for example, in Japanese Patent Application Laid-Open (JP-A) No. 2002-220444 or in Japanese Patent Application Laid-Open (JP-A) No. 2002-146003.

In the acylation, the amount of use of the aliphatic acid anhydride is preferably 1 to 1.2 mole multiple equivalent, more preferably 1.05 to 1.1 mole multiple equivalent, relative to the total amount of the phenolic hydroxyl group and the amino group. When the amount of addition of the aliphatic acid anhydride is less than 1 mole multiple equivalent, the acylated product or the source material monomer tends to be sublimed at the time of polymerization to close the reaction system. When the amount of addition of the aliphatic acid anhydride exceeds 1.2 mole multiple equivalent, the coloring of the obtained liquid crystal polyester tends to be considerable.

The acylation is preferably carried out at a temperature of from 130 to 180° C. for 5 minutes to 10 hours, and is more preferably carried out at a temperature of 140 to 160° C. for 10 minutes to 3 hours.

In view of the price and the handling property, the aliphatic acid anhydride used for acylation is preferably acetic anhydride, propionic anhydride, butyric anhydride, isobutyric anhydride, or a mixture of two or more kinds selected from these, and is especially preferably acetic anhydride.

The polymerization succeeding the acylation is preferably carried out by raising the temperature at a ratio of 0.1 to 50° C./min at a temperature of from 130 to 400° C., more preferably by raising the temperature at a ratio of 0.3 to 5° C./min at a temperature of from 150 to 350° C.

Also, in the polymerization, the acyl group of the acylated product is preferably 0.8 to 1.2 mole multiple equivalent of the carboxyl group.

At the time of acylation and/or polymerization, in order to let the equilibrium move, it is preferable to remove the aliphatic acid generated as a byproduct or unreacted aliphatic acid anhydride out of the system by evaporation, or the like.

Here, the acylation or polymerization may be carried out in the presence of a catalyst. The catalyst may be one conventionally known as a catalyst for polymerization of polyester, and may be, for example, a metal salt catalyst such as magnesium acetate, stannous acetate, tetrabutyl titanate, lead acetate, sodium acetate, potassium acetate, or antimony trioxide, an organic compound catalyst such as N,N-dimethylaminopyridine or N-methylimidazole, or the like.

Among these catalysts, a heterocyclic compound having two or more nitrogen atoms such as N,N-dimethylaminopyridine or N-methylimidazole is preferably used (See, Japanese Patent Application Laid-Open (JP-A) No. 2002-146003).

The catalyst may be typically introduced simultaneously with the monomer, and it is not necessary to remove the catalyst after the acylation. When the catalyst is not removed, the process may proceed from the acylation directly to the polymerization.

The liquid crystal polyester obtained by such a polymerization can be used, as it is, in the present invention. However, in order to improve the characteristics of heat resistance or liquid crystallinity further, it is preferable to attain a higher polymerization degree. For attaining such a higher polymerization degree, it is preferable to carry out a solid phase polymerization. A series of operations related to this solid phase polymerization will be described. The liquid crystal polyester obtained by the above described polymerization and having a comparatively low molecular weight is taken out and ground to have a powder form or flake form. Subsequently, the ground liquid crystal polyester is subjected to a heat treatment in an atmosphere of an inert gas such as nitrogen within a range from 20 to 350° C. for 1 to 30 hours in a solid phase state, whereby the solid phase polymerization can be carried out. The solid phase polymerization may be carried out either while stirring or in a state of being quietly kept to stand without stirring. Here, from the viewpoint of obtaining a later-mentioned liquid crystal polyester having a suitable fluidization starting temperature, the suitable condition for solid phase polymerization will be described in detail. The reaction temperature preferably exceeds 210° C., more preferably within a range from 220° C. to 350° C. The reaction time is preferably selected from 1 to 10 hours.

As the liquid crystal polyester used in the present invention, when the fluidization starting temperature is 250° C. or higher, an effect is exhibited such that the adhesiveness between the conductive layer and the insulation layer can be easily obtained, and such an adhesiveness does not decrease considerably by a later-mentioned thin film processing of the substrate. The fluidization starting temperature used herein refers to a temperature at which the melt viscosity of liquid crystal polyester becomes 4800 Pa·s or less under a pressure of 9.8 MPa in an evaluation of the melt viscosity by a flow tester. Here, this fluidization starting temperature is known to a person skilled in the art as a standard of the molecular weight of liquid crystal polyester (“Liquid Crystal Polymer Synthesis, Molding, and Application” edited by Naoyuki KOIDE, pp. 95-105, CMC, issued on Jun. 5, 1987).

The fluidization starting temperature of the liquid crystal polyester is more preferably 250° C. or higher and 300° C. or lower. When the fluidization starting temperature is 300° C. or lower, the solubility of the liquid crystal polyester to a solvent will be improved, and moreover, when the later-mentioned solution composition is obtained, the viscosity thereof will not be considerably large, so that the handling property of the solution composition tends to be good. From such a viewpoint, a liquid crystal polyester having a fluidization starting temperature of 260° C. or higher and 290° C. or lower is further more preferable. Here, in order to control the fluidization starting temperature of the liquid crystal polyester to be within such a suitable range, the polymerization condition of the above described solid phase polymerization may be suitably optimized.

### <Solution Composition>

In order to obtain an insulation layer constituting the substrate of the present invention, it is preferable to use a solution composition containing a liquid crystal polyester and a solvent, in particular a solution composition obtained by dissolving a liquid crystal polyester into a solvent.

When the above-described suitable liquid crystal polyester, in particular a liquid crystal polyester containing the structural unit (3′), is used as the liquid crystal polyester, the liquid crystal polyester exhibits a sufficient solubility to a non-protonic solvent without containing a halogen atom.

Here, the non-protonic solvent that does not contain a halogen atom may be, for example, an ether-series solvent such as diethyl ether, tetrahydrofuran, or 1,4-dioxane, a ketone-series solvent such as acetone or cyclohexanone, an ester-series solvent such as ethyl acetate, a lactone-series solvent such as γ-butyrolactone, a carbonate-series solvent such as ethylene carbonate or propylene carbonate, an amine-series solvent such as triethylamine or pyridine, a nitrile-series solvent such as acetonitrile or succinonitrile, amide-series solvent such as N,N-dimethylformamide, N,N-dimethylacetamide, tetramethylurea, or N-methylpyrrolidone, a nitro-series solvent such as nitromethane or nitrobenzene, a sulfur-series solvent such as dimethyl sulfoxide or sulfolane, a phosphorus-series solvent such as hexamethylphosphoric acid amide or tri-n-butylphosphoric acid, or the like. Here, the solvent-solubility of the above-described liquid crystal polyester refers to the fact that it is soluble to at least one non-protonic solvent selected from these solvents.

When a non-protonic solvent such as described above is used in the solution composition, it is preferable that 20 to 50 parts by weight, preferably 22 to 40 parts by weight of the liquid crystal polyester is dissolved relative to 100 parts by weight of the non-protonic solvent. When the liquid crystal polyester content relative to the solution composition is within such a range, the efficiency of impregnating the sheet with the solution composition will be good in producing a prepreg, and an inconvenience such as generation of thickness unevenness is less liable to occur in removing the solvent by drying after impregnation.

Also, to the above described solution composition, one kind or two or more kinds of resins other than the liquid crystal polyester such as a thermoplastic resin such as polypropylene, polyamide, polyester, polyphenylene sulfide, polyether ketone, polycarbonate, polyether sulfone, polyphenyl ether and denatured products thereof, or polyetherimide; an elastomer represented by a copolymer of glycidyl methacrylate and polyethylene, or a thermosetting resin such as a phenolic resin, an epoxy resin, a polyimide resin, or a cyanate resin may be added. However, even in a case of using such a different resin, these different resins are preferably soluble to the solvent used in the solution composition.

Also, the above described solution composition may be filtrated with a filter or the like in accordance with the needs, so as to remove fine foreign substances contained in the solution.

### <Inorganic Filler>

The insulation layer preferably contains an inorganic filler in addition to the sheet and the liquid crystal polyester. Such an insulation layer having an inorganic filler is preferred because the insulation layer tends to have a lowered the linear expansion coefficient in the surface direction and also tends to increase the heat conductivity to improve heat dissipation propertes of the resulting substrate.

In this case, by using the inorganic filler in combination with the solution composition, the obtained insulation layer can be allowed to contain the inorganic filler. Such an inorganic filler may be, for example, an inorganic filler such as silica, alumina, titanium oxide, barium titanate, strontium titanate, aluminum hydroxide, or calcium carbonate. From the viewpoint of further reducing the linear expansion coefficient in the surface direction, an inorganic filler made of silicon oxide and/or aluminum oxide is preferable. Such an inorganic filler is preferably silica and/or alumina. The inorganic filler may have any shape such as in a particle form, a fiber form, or a plate form. In view of availability and cost, those in a particle form are preferable. Here, in this case, the content of the inorganic filler is preferably 5 to 90 wt %, more preferably 10 to 80 wt % based on the total weight of the liquid crystal polyester and the inorganic filler.

An organic filler or additive can also be used besides the inorganic filler. The kind and the amount of use of such an organic filler or additive are determined within a range that does not considerably deteriorate the purpose of the present invention. Specific examples of the organic filler include organic fillers made of a thermoplastic resin such as a cured epoxy resin, a cross-linked benzoguanamine resin, a cross-linked acrylic polymer, polyamide, polyester, polyphenylene sulfide, polyether ketone, polycarbonate, polyether sulfone, polyphenyl ether and denatured products thereof, and polyetherimide, organic fillers made of a thermosetting resin such as a phenolic resin, an epoxy resin, a polyimide resin, and a cyanate resin, and the like. Also, the additive may be, for example, a silane coupling agent, an antioxidant, an ultraviolet absorber, or the like.

<Sheet Made of Inorganic Fibers and/or Carbon Fibers>

The sheet used in the present invention is a paper, fabric, non-woven cloth sheet, or the like having a gas permeability, which is made of inorganic fibers and/or carbon fibers. Here, the inorganic fibers are ceramic fibers represented by glass, and examples thereof include glass fibers, alumina-series fibers, silicon-containing ceramic-series fibers, and the like. Among these, a sheet mainly made of glass fibers, namely, a glass cloth, is preferable because the obtainability is good.

As the glass cloth, a glass cloth made of alkali-containing glass fibers, non-alkali glass fibers, or low dielectric constant glass fibers is preferable. Also, as the fibers constituting the glass cloth, ceramic fibers made of ceramics other than glass or carbon fibers may be mingled into a part thereof. Also, the fibers constituting the glass cloth may be subjected to surface treatment with a coupling agent such as an aminosilane-series coupling agent, an epoxysilane-series coupling agent, or a titanate-series coupling agent.

As a method for producing a glass cloth made of these fibers, examples thereof include a method of dispersing the fibers constituting the glass cloth into water, adding a sizing agent such as an acrylic resin in accordance with the needs, and drying after making paper with a paper machine so as to obtain a non-woven cloth, or a method of using a known weaving machine.

As a method of weaving the fibers, plain weave, satin weave, twill weave, nanako weave, or the like, can be used. The weaving density is preferably 10 to 100 bundles/25 mm. As the glass cloth, those having a mass per unit area of 10 to 300 g/m² are preferably used. The thickness of the glass cloth is typically about 10 to 200 and preferably 10 to 180 μm.

Also, a glass cloth easily obtainable from the market can be used as well. As such a glass cloth, various ones are commercially available as an insulation impregnation base material of an electronic component, and can be obtained from Asahi Kasei E-material Corp., Nitto Bouseki Co., Ltd., Arisawa Seisakusho Co., Ltd., or the like. Here, regarding the commercially available glass cloth, examples thereof include 1035, 1078, 2116, and 7628 in terms of IPC naming as the glass cloth having a preferable thickness.

### <Method of Producing a Substrate>

The insulation layer of the substrate of the present invention is preferably one that is produced by using a resin-impregnated base material (prepreg) formed with a liquid crystal polyester soluble in a solvent and the above described sheet (preferably a glass cloth) such as exemplified above. In particular, a prepreg obtained by impregnating the sheet with the solution composition and thereafter removing the solvent is preferable. The total amount of the liquid crystal polyester and the optional other composition (if any) such as an inorganic filler, both of which are attached to the prepreg after removal of the solvent, is preferably 30 to 80 wt %, more preferably 40 to 70 wt %, relative to the weight of the obtained prepreg.

Here, a method of producing a substrate in the case of using a glass cloth suitable as a sheet will be described.

In order to impregnate the glass cloth with a solution composition, it can be carried out typically by preparing an immersion tank loaded with the solution composition and immersing the glass cloth into this immersion tank. Here, the above-mentioned suitable amount of attached liquid crystal polyester and optional other composition can be easily controlled by suitably optimizing the liquid crystal polyester content of the used solution composition, the time for immersing into the immersion tank, and the speed of pulling up the glass cloth impregnated with the solution composition.

In this manner, a prepreg can be produced by removing the solvent from the glass cloth impregnated with the solution composition. The method of removing the solvent is not particularly limited; however, for the sake of convenience in operations, it is preferably carried out by evaporation of the solvent, and also heating, pressure reduction, ventilation, and a method of combining these are used. Also, for the production of a prepreg, a heating treatment may be further carried out after removing the solvent. By such a heating treatment, the liquid crystal polyester contained in the prepreg after removal of the solvent can be further highly polymerized. As a processing condition for this heating treatment, an example thereof includes a method of performing the heating treatment at 240 to 330° C. for 1 to 30 hours in an inert gas atmosphere such as nitrogen. Here, from the viewpoint of obtaining a substrate having an improved heat resistance, the processing condition for this heating treatment is preferably such that the heating temperature thereof exceeds 250° C., and more preferably, the heating temperature is within the range of 260 to 320° C. The processing time of the heating treatment is preferably selected from 1 to 10 hours in view of the productivity.

Regarding the prepreg produced in this manner, the linear expansion coefficient in the surface direction as determined by a Thermal Mechanical Analysis (TMA) apparatus (manufactured by Seiko Instruments Inc.) [temperature range: 50° C. to 100° C.] according to JIS C6481 “the method of testing a copper-clad laminate plate for a printed wiring board” will be extremely small. The linear expansion coefficient is preferably 13 ppm/° C. or less, more preferably 10 ppm/° C. or less, still more preferably 9 ppm/° C. or less. Here, typically, such a prepreg does not shrink, so that the lower limit of the linear expansion coefficient in the surface direction will be 0 ppm/° C. or more.

The reason why the prepreg has an extremely small linear expansion coefficient is not necessarily clear. However, the present inventors and others surmise as follows. When a sheet made of inorganic fibers and/or organic fibers is impregnated with a solvent-soluble liquid crystal polyester particularly as a solution composition, the solution composition can efficiently fill the gap of the sheet. In the prepreg obtained in this manner, void-shaped defects are hardly formed in the prepreg, so that it will be hardly affected by the expansion of the gas present in the void-shaped defects, or the like. Also, the present inventors and others have found out that the prepreg obtained by the method of impregnating the sheet with a solvent-soluble liquid crystal polyester as a solution composition exhibits a good adhesiveness between the liquid crystal polyester and the fibers that form the sheet, as compared with a conventional prepreg obtained by the melting method of melting the liquid crystal polyester and impregnating the sheet with it. It is conjectured that the efficiency pertaining to such impregnation and the adhesiveness act synergistically to reduce the linear expansion coefficient.

Next, after mounting a LED, a conductive layer for forming an interconnect that can electrically join with the LED is formed on one surface of the obtained prepreg, and a heat-dissipation plate for dissipating the heat generated at the time of operation of the LED efficiently to the outside is laminated on the other surface, whereby the substrate of the present invention is produced.

The conductive layer preferably contains copper in view of exhibiting an excellent electric conductivity, and those made of copper or copper alloy are preferable.

The heat-dissipation plate preferably contains copper or aluminum, namely, is made of metal, in view of exhibiting an excellent heat dissipation property, and those made of copper or copper alloy are preferable.

As a method for laminating such a conductive layer or heat-dissipation plate on the prepreg, examples thereof include a method of laminating a metal foil (copper foil etc.) containing copper on the prepreg, a method of coating the upper part of the prepreg with fine metal particles (fine copper particles etc.), and the like.

As the method of laminating the metal foil, examples thereof include a method of bonding the metal foil to the prepreg with use of an adhesive agent, a method of thermally fusing the metal foil with the prepreg by thermal pressing, and the like.

When the adhesive agent is used, a commercially available epoxy resin-series adhesive agent or acrylic resin-series adhesive agent can be used.

Also, as the processing condition in the case of thermally pressing, it can be suitably optimized in accordance with the scale and shape of the prepreg to be used or the thickness and kind of the metal foil to be used; however, it is particularly preferable to perform thermal pressing in vacuum. Here, regarding the processing condition in the case of thermally pressing, it is preferable that the processing temperature and the processing pressure are suitably optimized so that the obtained laminate body may exhibit a good surface smoothness. For this processing temperature, the temperature condition of the heat treatment used at the time of producing the prepreg used in the thermal pressing can be used as a base point. Specifically, assuming that the maximum temperature of the temperature condition pertaining to the heat treatment used at the time of producing the prepreg is Tₘₐₓ [°C], it is preferable to perform the thermal pressing at a temperature that exceeds this Tₘₐₓ, and it is even more preferable to perform the thermal pressing at a temperature of Tₘₐₓ+5 [° C.] or higher. The upper limit of the temperature pertaining to the thermal pressing is selected so as to be lower than the decomposition temperature of the liquid crystal polyester contained in the prepreg to be used. Preferably, the upper limit is selected so as to be lower than the decomposition temperature by 30° C. or more. Here, the decomposition temperature herein referred to is determined by known means such as thermogravimetric reduction analysis. Also, the processing temperature of the thermal pressing is selected from 1 to 30 hours, and the pressing pressure is selected from 1 to 30 MPa.

Also, as a method of coating with fine metal particles, particularly with fine copper particles, the plating method, the screen printing method, the sputtering method, or the like, can be used. Among these, the plating method is preferable as the coating method. Specifically, it is preferable to use nonelectrolytic plating or electrolytic plating.

Further, in order to improve the characteristics of the conductive layer obtained by such a plating method further, the conductive layer subjected to plating is preferably further subjected to a heat treatment. Regarding the processing condition for such a heat treatment, a condition equivalent to the condition described as the processing condition of the above described thermal pressing is adopted.

Among the above, in view of producing a conductive layer and a heat-dissipation plate having a suitable material, namely, containing copper, it is preferable to laminate the conductive layer and the heat-dissipation plate onto the prepreg with use of a copper foil in view of the operability. Also, use of the copper foil is advantageous in view of cost.

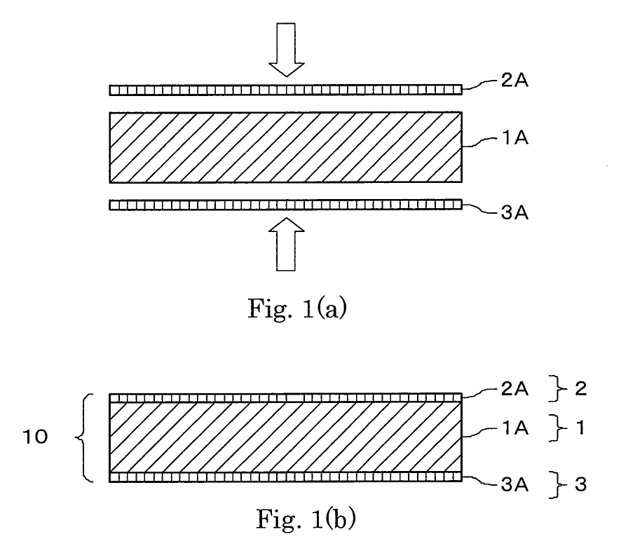

Here, a summary of a method of producing a substrate by using a copper foil for lamination of the conductive layer and the heat-dissipation plate will be described with reference to FIGS. 1(a) and 1(b).

First, a prepreg 1A is prepared that is produced by impregnating the above described sheet (preferably a glass cloth) with a solution composition containing a solvent-soluble liquid crystal polyester, an inorganic filler to (preferably spherical silica), and a solvent (preferably non-protonic polar solvent), followed by removing the solvent.

Next, copper foils 2A, 3A are laminated on both sides of this prepreg 1A by thermal pressing (FIG. 1(a)). A substrate 10 is obtained by such thermal pressing (FIG. 1(b)). In the substrate 10, the liquid crystal polyester that is present in the prepreg 1A is polymerized by the heat treatment involved in the thermal pressing, thereby to form an insulation layer 1 provided with the liquid crystal polyester that has been more highly polymerized. Regarding the copper foils 2A, 3A laminated in the substrate 10, one will be the conductive layer, and the other will be the heat-dissipation plate.

### <Production of Chip LED Package>

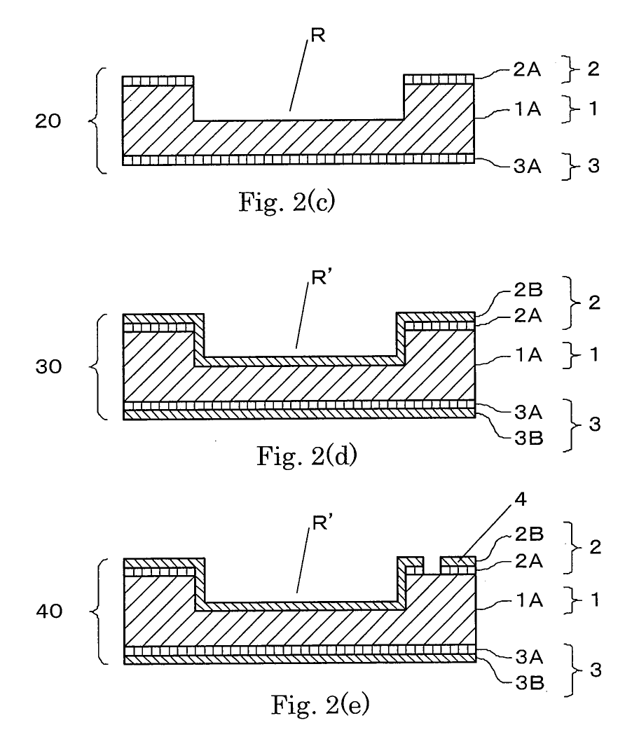

Next, a summary of the step for producing a chip LED package with use of the substrate 10 that has been obtained as described above will be described with reference to FIGS. 2(c) to 2(e).

First, a region R for mounting the LED is subjected to a thin film treatment to obtain a thin-film-treated substrate 20 (FIG. 2(c)). In order to perform the thin film treatment on this region R, a drilling treatment or a laser treatment is adopted. Here, in performing the thin film treatment on such a region R, attention is paid so that the thin film part will not reach the heat-dissipation plate 3B.

Copper foils 2B, 3B are further deposited by plating or the like on both sides of the thin-film-treated substrate 20 obtained in this manner, thereby to obtain a plating-formed substrate 30 (FIG. 2(d)).

Next, an interconnect 4 is formed in the conductive layer 2 made of the copper foil 2A and the copper layer 2B (FIG. 2(e)). Typically, etching (processing) is used for forming such an interconnect. First, masking is carried out so that the pattern of the interconnect will be a predetermined pattern. In the masked copper foil part and in the copper foil part not masked, the latter copper foil part is removed by etching process called the wet method (chemical agent treatment). As the chemical agent used for this etching process, an example thereof includes an aqueous solution of ferric chloride. Also, for the masking, a commercial etching resist or dry film may be used.

Subsequently, the etching resist or dry film is removed from the masked copper foil part with use of acetone or an aqueous solution of sodium hydroxide. In this manner, the predetermined interconnect 4 can be formed. The interconnect-formed substrate 40 having the interconnect formed thereon will be one provided with the interconnect 4 that establishes electrical connection between the region R′ for mounting the LED and the mounted LED.

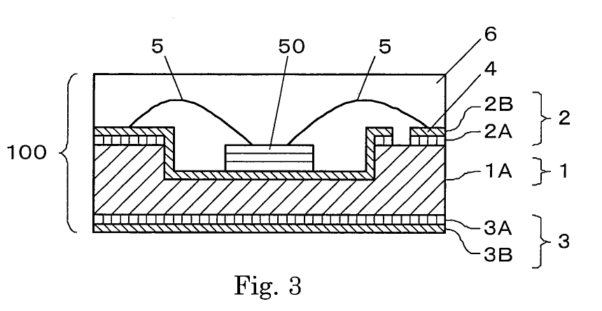

Next, as shown in FIG. 3, a LED 50 is mounted on the region R′. For this mounting, first, solder is applied on the region R′, and a LED 50 is placed thereon. Thereafter, by passing through a reflow furnace or the like to melt the solder, the LED 50 is fixed to the interconnect-formed substrate 40. A metal interconnect 5 that establishes electrical connection between the fixed LED 50 and the interconnect 4 is formed by bonding, or the like.

Further, with use of transfer molding or the like, the LED 50 is sealed with a sealing resin 6. Here, the transfer molding refers to a technique of pressing the resin into a clamped mold. By such a series of operations, the chip LED package 100 is produced. In such a chip LED package 100, a via hole that connects between the conductive layer 2 and the heat dissipation-plate 3 may be provided. By providing such a via hole, the heat generated in the LED 50 or the interconnect 4 is efficiently passed to the heat-dissipation plate side, whereby an efficient heat dissipation can be carried out.

The invention being thus described, it will be apparent that the same may be varied in many ways. Such variations are to be regarded as within the spirit and scope of the invention, and all such modifications as would be apparent to one skilled in the art are intended to be within the scope of the following claims.

### EXAMPLES

Hereafter, the present invention is described in more detail by following Examples, which should not be construed as a limitation upon the scope of the present invention. In the examples, a method of evaluating the obtained substrate 1 is as follows. Heat resistance

A pad with φ2.0 mm was formed on one surface of the substrate 1 using a ferric chloride solution (manufactured by Kida Co., Ltd.; 40° Baumé). After pressing a soldering iron of 350° C. for 5 seconds, 10 seconds, and 30 seconds in a state with solder or in a state without solder, the state of the surface was observed by eye inspection. The case in which delamination or swelling of the copper foil was not confirmed was evaluated as ◯, and the case in which delamination or swelling of the copper foil was confirmed was evaluated as ×.

### Linear Expansion Coefficient

All the copper foils were removed from both surfaces of the substrate 1 using a ferric chloride solution (manufactured by Kida Co., Ltd.; 40° Baumé). According to JIS C6481 “the method of testing a copper-clad laminate plate for printed wiring board”, the linear expansion coefficient in the surface direction was evaluated using a Thermal Mechanical Analysis (TMA) apparatus (manufactured by Seiko Instruments Inc.) (temperature range: 50 to 100° C., 1St scan).

### Thermal Conductivity

All the copper foils were removed from both surfaces of the substrate 1 using a ferric chloride solution (manufactured by Kida Co., Ltd.; 40° Baumé). The thermal diffusivity was measured using a thermal wave thermometric analysis method measuring apparatus (“ai-Phase Mobile1” manufactured by Ai-Phase Co., Ltd.); the specific heat was measured using DSC (“DSC7” manufactured by PERKIN ELMER Co., Ltd.); the specific weight was measured using an automatic specific weight measuring apparatus (“ASG-320K” manufactured by Kanto Measure Co., Ltd.); and the product of the thermal diffusivity, the specific heat, and the specific weight was calculated as the heat conductivity.

### Example 1

### (1) Production of Liquid Crystal Polyester

A reactor equipped with a stirring apparatus, a torque-meter, a nitrogen gas introduction pipe, a thermometer, and a reflux condenser was loaded with 1976 g (10.5 mol) of 2-hydroxy-6-naphthoic acid, 1474 g (9.75 mol) of 4-hydroxyacetanilide, 1620 g (9.75 mol) of isophthalic to acid, and 2374 g (23.25 mol) of acetic anhydride. After replacing the inside of the reactor sufficiently with nitrogen gas, the temperature was raised to 150° C. over 15 minutes under nitrogen gas stream, and the reflux was carried out for 3 hours while maintaining the temperature.

Thereafter, while removing the effluent byproduct acetic acid and unreacted acetic anhydride, the temperature was raised to 300° C. over 170 minutes. The time point at which the rise of the torque was recognized was regarded as the end of reaction, and the contents were taken out to obtain a prepolymer having a comparatively low molecular weight. The prepolymer taken out was cooled to room temperature and ground with use of a rough grinder. The fluidization starting temperature of the obtained prepolymer was measured using a flow tester (“CFT-500” manufactured by Shimadzu Corporation Co., Ltd.), and the result was 235° C. Next, this prepolymer powder was subjected to solid phase polymerization at 223° C. for 3 hours in a nitrogen atmosphere, so as to obtain a liquid crystal polyester in a powder form. The fluidization starting temperature of this liquid crystal polyester was measured in the same manner as above, and the result was 270° C.

### (2) Preparation of Solution Composition

A solution composition was obtained by adding 2200 g of the liquid crystal polyester obtained in the above (1) to 7800 g of N,N′-dimethylacetamide (DMAc) and heating the mixture at 100° C. for 2 hours. The viscosity of this solution composition was measured at a temperature of 23° C. using a B-type viscometer (“TVL-20 type” manufactured by Toki Sangyo Co., Ltd.; rotor No. 21 (rotation number: 5 rpm)), and the result was 320 cP.

### (3) Production of Prepreg

A glass cloth having a thickness of 96 μm (IPC naming: 2116) (manufactured by Arisawa Manufacturing Co., Ltd.) was impregnated with the solution composition obtained in the above (2), and the solvent was evaporated under a condition with a set temperature of 160° C. by a hot wind type dryer, so as to obtain a prepreg 1. In the obtained prepreg 1, the attached amount of the liquid crystal polyester to the glass cloth was about 35 wt %, with an average thickness of 82 μm and with a thickness variation of 3%.

### (4) Production of Substrate

First, the prepreg 1 was subjected to a heat treatment at 290° C. for 3 hours in a nitrogen atmosphere by using a hot wind type dryer. Two sheets of the prepreg 1 subjected to the heat treatment were superposed, and a copper foil having a thickness of 18 μm (“3EC-VLP” manufactured by Mitsui Mining & Smelting Co., Ltd.) was superposed on both sides thereof. Then, the resultant was integrated by thermal pressing under a condition of 340° C., 20 minutes, and 5 MPa using a high-temperature vacuum pressing machine (“high-temperature vacuum press VH1-1765” manufactured by Kitagawa Seiki Co., Ltd.) to obtain a' substrate 1. The heat resistance and the linear expansion coefficient were evaluated with respect to the obtained substrate 1. The results are shown in Table 1.

### Example 2

A prepreg 1 was obtained to obtain a substrate 1 in the same manner as in Example 1 except that a glass cloth having a thickness of 45 μm (IPC naming: 1078) (manufactured by Arisawa Manufacturing Co., Ltd.) was used in Example 1(3). In the obtained prepreg 1, the attached amount of the liquid crystal polyester to the glass cloth was about 55 wt %, with an average thickness of 55 μm and with a thickness variation of 3%. The heat resistance and the linear expansion coefficient were evaluated with respect to the obtained substrate 1. The results are shown in Table 1.

### Comparative Example 1

Linear expansion coefficient was evaluated using a commercially available epoxy resin glass cloth base material copper-clad plate (“MCL-E67” manufactured by Hitachi Chemical Co., Ltd., having a thickness of 100 μm including a copper foil thickness of 18 μm). The result is shown in Table 1.

### Comparative Example 2

Heat resistance was evaluated with respect to a commercially available liquid crystal polyester two-sided plate (“Espanex L-LB09-50-09NE” manufactured by Nippon Steel Chemical Co., Ltd., having a thickness of 50 μm including a copper foil thickness of 9 μm). The result is shown in Table 1.

### Example 3

A prepreg 1 was obtained to obtain a substrate 1 in the same manner as in Example 1 except that a silica filler (“CA-0020” manufactured by Korea Semiconductor Material Co., Ltd.) was added to the solution composition obtained in Example 1(2) by 20.0 vol % relative to the liquid crystal polyester, and that a glass cloth having a thickness of 45 μm (IPC naming: 1078) (manufactured by Arisawa Manufacturing Co., Ltd.) was used in Example 1(3). In the obtained prepreg 1, the total of the attached amounts of the liquid crystal polyester and the silica filler to the glass cloth was about 60 wt %, with an average thickness of 60 μm and with a thickness variation of 3%. The linear expansion coefficient was evaluated with respect to the obtained substrate 1. The result is shown in Table 1.

### Example 4

A prepreg 1 was obtained to obtain a substrate 1 in the same manner as in Example 1 except that spherical alumina having a volume-average particle size of 0.3 μm (“Sumicorundum AA-0.3” manufactured by Sumitomo Chemical Co., Ltd.), spherical alumina having a volume-average particle size of 1.5 μm (“Sumicorundum AA-1.5” manufactured by Sumitomo Chemical Co., Ltd.), and spherical alumina having a volume-average particle size of 18 μm (“Sumicorundum AA-18” manufactured by Sumitomo Chemical Co., Ltd.) were added to the solution composition obtained in Example 1(2) respectively by 3.1 vol %, 6.1 vol %, and 30.8 vol % relative to the liquid crystal polyester. In the obtained prepreg 1, the total of the attached amounts of the liquid crystal polyester and the three kinds of spherical alumina to the glass cloth was about 41 wt %, with an average thickness of 109 μm and with a thickness variation of 3%. The linear expansion coefficient and the thermal conductivity were evaluated with respect to the obtained substrate 1. The results are shown in Table 1.

### Example 5

A prepreg 1 was obtained to obtain a substrate 1 in the same manner as in Example 1 except that spherical alumina having a volume-average particle size of 0.3 (“Sumicorundum AA-0.3” manufactured by Sumitomo Chemical Co, Ltd.), spherical alumina having a volume-average particle size of 1.5 μm (“Sumicorundum AA-1.5” manufactured by Sumitomo Chemical Co., Ltd.), and spherical alumina having a volume-average particle size of 18 μm (“Sumicorundum AA-18” manufactured by Sumitomo Chemical Co., Ltd.) were added to the solution composition obtained in Example 1(2) respectively by 5.8 vol %, 11.4 vol %, and 57.7 vol % relative to the liquid crystal polyester. In the obtained prepreg 1, the total of the attached amounts of the liquid crystal polyester and the three kinds of spherical alumina to the glass cloth was about 72 wt %, with an average thickness of 179 μm and with a thickness variation of 3%. The linear expansion coefficient and the thermal conductivity were evaluated with respect to the obtained substrate 1. The results are shown in Table 1.

### Example 6

A prepreg 1 was obtained to obtain a substrate 1 in the same manner as in Example 1 except that spherical alumina having a volume-average particle size of 0.3 μm (“Sumicorundum AA-0.3” manufactured by Sumitomo Chemical Co., Ltd.), spherical alumina having a volume-average particle size of 1.5 μm (“Sumicorundum AA-1.5” manufactured by Sumitomo Chemical Co., Ltd.), and spherical alumina having a volume-average particle size of 18 μm (“Sumicorundum AA-18” manufactured by Sumitomo Chemical Co., Ltd.) were added to the solution composition obtained in Example 1(2) respectively by 3.1 vol %, 6.1 vol %, and 30.8 vol % relative to the liquid crystal polyester, and that a glass cloth having a thickness of 45 μm (IPC naming: 1078) (manufactured by Arisawa Manufacturing Co., Ltd.) was used in Example 1(3). In the obtained prepreg 1, the total of the attached amounts of the liquid crystal polyester and the three kinds of spherical alumina to the glass cloth was about 64 wt %, with an average thickness of 76 μm and with a thickness variation of 3%. The linear expansion coefficient and the thermal conductivity were evaluated with respect to the obtained substrate 1. The results are shown in Table 1.

### Example 7

A prepreg 1 was obtained to obtain a substrate 1 in the same manner as in Example 1 except that spherical alumina having a volume-average particle size of 0.3 μm (“Sumicorundum AA-0.3” manufactured by Sumitomo Chemical Co., Ltd.), spherical alumina having a volume-average particle size of 1.5 μm (“Sumicorundum AA-1.5” manufactured by Sumitomo Chemical Co., Ltd.), and spherical alumina having a volume-average particle size of 18 μm (“Sumicorundum AA-18” manufactured by Sumitomo Chemical Co., Ltd.) were added to the solution composition obtained in Example 1(2) respectively by 5.8 vol %, 11.4 vol %, and 57.7 vol % relative to the liquid crystal polyester, and that a glass cloth having a thickness of 45 μm (IPC naming: 1078) (manufactured by Arisawa Manufacturing Co., Ltd.) was used in Example 1(3). In the obtained prepreg 1, the total of the attached amounts of the liquid crystal polyester and the three kinds of spherical alumina to the glass cloth was about 84 wt %, with an average thickness of 134 μm (thickness distribution in the width direction of the base material) and with a thickness variation of 3%. The linear expansion coefficient and the thermal conductivity were evaluated with respect to the obtained substrate 1. The results are shown in Table 1.

TABLE 1

| | | Example | Example | Example | Comparative | Comparative | Example | Example | Example | Example |
|---|---|---|---|---|---|---|---|---|---|---|
| | | 1 | 2 | 3 | Example 1 | Example 2 | 4 | 5 | 6 | 7 |
| Heat | 5 seconds | ∘ | ∘ | ∘ | — | x | ∘ | ∘ | ∘ | ∘ |
| resistance | 10 seconds | ∘ | ∘ | ∘ | — | x | ∘ | ∘ | ∘ | ∘ |
| (with | 30 seconds | ∘ | ∘ | ∘ | — | x | ∘ | ∘ | ∘ | ∘ |
| solder) | | | | | | | | | | |
| Heat | 5 seconds | ∘ | ∘ | ∘ | — | x | ∘ | ∘ | ∘ | ∘ |
| resistance | 10 seconds | ∘ | ∘ | ∘ | — | x | ∘ | ∘ | ∘ | ∘ |
| (without | 30 seconds | ∘ | ∘ | ∘ | — | x | ∘ | ∘ | ∘ | ∘ |
| solder) | | | | | | | | | | |
| Linear | (ppm/° C.) | 6.3 | 6.6 | 7.3 | 14.7 | — | 4.0 | 5.6 | 5.7 | 5.9 |
| expansion | | | | | | | | | | |
| coefficient | | | | | | | | | | |
| Thermal | (W/m · K) | — | — | — | — | — | 0.9 | 1.7 | 1.1 | 2.4 |
| conductivity | | | | | | | | | | |

What is claimed is:

1. A substrate applicable in a chip LED package, the substrate having a conductive layer, an insulation layer and a heat-dissipation plate in this order, wherein the insulation layer comprises a liquid crystal polyester soluble in a solvent and a sheet comprising inorganic fibers and/or organic fibers.

2. The substrate according to claim 1, wherein the insulation layer contains an inorganic filler.

3. The substrate according to claim 2, wherein the inorganic filler comprises silicon oxide and/or aluminum oxide.

4. The substrate according to claim 1, wherein the insulation layer has a linear expansion coefficient of 13 ppm/° C. or less as determined at a temperature in the range of from 50° C. to 100° C.

5. The substrate according to claim 1, wherein the liquid crystal polyester contains 30 to 45% by mole of a structural unit represented by the following formula (1), 27.5 to 35% by mole of a structural unit represented by the following formula (2) and 27.5 to 35% by mole of a structural unit represented by the following formula (3), all amounts being relative to the total amount of all the structural units,
—O—Ar¹—CO— (1)
—CO—Ar²—CO— (2)
—X—Ar³—Y— (3)
wherein Ar¹ represents a phenylene group or a naphthylene group; Ar² represents a phenylene group, a naphthylene group, or a group represented by the following formula (4); and Ar³ represents a phenylene group or a group represented by the following formula (4); X and Y each independently represent O or NH; and one or more of the hydrogen atoms attached to the aromatic rings Ar¹, Ar², and Ar³ may each independently be substituted with a halogen atom, an alkyl group, or an aryl group:
—Ar¹¹—Z—Ar¹²— (4)
wherein Ar¹¹ and Ar¹² each independently represent a phenylene group or a naphthylene group, and Z represents O, CO, or SO₂.

6. The substrate according to claim 5, wherein either one or both of X and Y in the formula (3) are NH.

7. The substrate according to claim 1, wherein the liquid crystal polyester contains 30 to 45% by mole of at least one structural unit selected from the group consisting of a structural unit derived from p-hydroxybenzoic acid and a structural unit derived from 2-hydroxy-6-naphthoic acid, 27.5 to 35% by mole of a structural unit derived from 4-aminophenol, and 27.5 to 35% by mole of at least one structural unit selected from the group consisting of a structural unit derived from terephthalic acid, a structural unit derived from isophthalic acid, and a structural unit derived from 2,6-naphthalenedicarboxylic acid, the amount being relative to the total amount of all the structural units.

8. The substrate according to claim 1, wherein the sheet is a glass cloth.

9. A method for producing the substrate according to claim 1, the method comprising the steps of impregnating the sheet with a solution composition containing a liquid crystal polyester and a solvent and removing the solvent.

10. The substrate according to claim 1, wherein the conductive layer contains copper.

11. The substrate according to claim 1, wherein the heat-dissipation plate contains copper.

12. A chip LED package comprising the substrate according to claim 1 and a light emitting diode.
